(19) United States
(12) Patent Application Publication
(10) Pub. No.: US 2009/0250713 A1
(43) Pub. Date: Oct. 8, 2009

(54) Reflective Contact for a Semiconductor Light Emitting Device

(75) Inventors: Henry Kwong-Hin Choy, Sunnyvale, CA (US); Daniel A. Steigerwald, Cupertino, CA (US)

Correspondence Address: PATENT LAW GROUP LLP, 2635 NORTH FIRST STREET, SUITE 223, SAN JOSE, CA, 95134, US

(73) Assignee: PHILIPS LUMILEDS LIGHTING COMPANY, LLC, San Jose, CA (US)

(21) Appl. No.: 12/098,381

(22) Filed: Apr. 4, 2008

(51) Int. Cl. H01L 33/00

(52) U.S. Cl. 257/98; 257/E33.001

(57) ABSTRACT

A light emitting device includes a semiconductor structure comprising a light emitting layer disposed between an n-type region and a p-type region. A contact is formed on the semiconductor structure, the contact comprising a reflective metal in direct contact with the semiconductor structure and an additional metal or semi-metal disposed within the reflective metal. In some embodiments, the additional metal or semi-metal is a material with higher electronegativity than the reflective metal. The presence of the high electronegativity material in the contact may increase the overall electronegativity of the contact, which may reduce the forward voltage of the device. In some embodiments, an oxygen-gathering material is included in the contact.

### BACKGROUND

1. Field of Invention

The present invention relates to a semiconductor light emitting device including a reflective contact.

2. Description of Related Art

Semiconductor light-emitting devices including light emitting diodes (LEDs), resonant cavity light emitting diodes (RCLEDs), vertical cavity laser diodes (VCSELs), and edge emitting lasers are among the most efficient light sources currently available. Materials systems currently of interest in the manufacture of high-brightness light emitting devices capable of operation across the visible spectrum include Group III-V semiconductors, particularly binary, ternary, and quaternary alloys of gallium, aluminum, indium, and nitrogen, also referred to as III-nitride materials. Typically, III-nitride light emitting devices are fabricated by epitaxially growing a stack of semiconductor layers of different compositions and dopant concentrations on a sapphire, silicon carbide, III-nitride, or other suitable substrate by metal-organic chemical vapor deposition (MOCVD), molecular beam epitaxy (MBE), or other epitaxial techniques. The stack often includes one or more n-type layers doped with, for example, Si, formed over the substrate, one or more light emitting layers in an active region formed over the n-type layer or layers, and one or more p-type layers doped with, for example, Mg, formed over the active region. Electrical contacts are formed on the n- and p-type regions.

Due to the high resistivity of p-type III-nitride layers, LED designs employ metallization along the p-type layers to provide p-side current spreading. When the device is mounted as a flip chip (such that light exits the device from a surface opposite the surface on which the contacts are formed), using highly reflective contact metallizations is critical to improve the extraction efficiency. The combination of low optical absorption and low contact resistivity in a manufacturable process is difficult to achieve for contacts on III-nitride devices. For example, silver makes a good p-type ohmic contact and is very reflective, but can suffer from poor adhesion to III-nitride layers and from susceptibility to electro-migration in humid environments which can lead to catastrophic device failure. Poor adhesion can cause high forward voltage. Aluminum is reasonably reflective but does not make good ohmic contact to p-type III-nitride materials, while other elemental metals are fairly absorbing (>25% absorption per pass in the visible wavelength regime). A possible solution, described in U.S. Pat. No. 6,486,499, is to use a multi-layer contact which includes a very thin semi-transparent ohmic contact to the semiconductor in conjunction with a thick reflective layer which acts as a current spreading layer. An optional barrier layer is included between the ohmic layer and the reflective layer. Including an ohmic layer between the semiconductor and a reflective contact metal may reduce the forward voltage of the device as compared to a device with a reflective contact metal in direct contact with the semiconductor, but may also reduce light output, due to absorption in the ohmic layer.

### SUMMARY

In accordance with embodiments of the invention, a light emitting device includes a semiconductor structure comprising a light emitting layer disposed between an n-type region and a p-type region. A contact is formed on the semiconductor structure, the contact comprising a reflective metal in direct contact with the semiconductor structure and an additional metal or semi-metal disposed within the reflective metal. In some embodiments, the additional metal or semi-metal is a material with higher electronegativity than the reflective metal. The presence of a high electronegativity material in the contact may increase the overall electronegativity of the contact, which may reduce the forward voltage of the device.

### BRIEF DESCRIPTION OF THE DRAWINGS

FIG. 1 illustrates a portion of a III-nitride light emitting device with a reflective p-contact including a single high electronegativity layer.

FIG. 2 illustrates a portion of a III-nitride light emitting device with a reflective p-contact including multiple high electronegativity layers.

FIG. 3 illustrates a III-nitride thin-film flip-chip light emitting device.

FIG. 4 illustrates a portion of a III-nitride light emitting device with a reflective p-contact including one or more alloy layers.

### DETAILED DESCRIPTION

In accordance with embodiments of the invention, a material with high electronegativity is embedded in a reflective metal contact. The high electronegativity material may improve the contact by reducing the forward voltage of the device, and may reduce electro migration of the reflective metal.

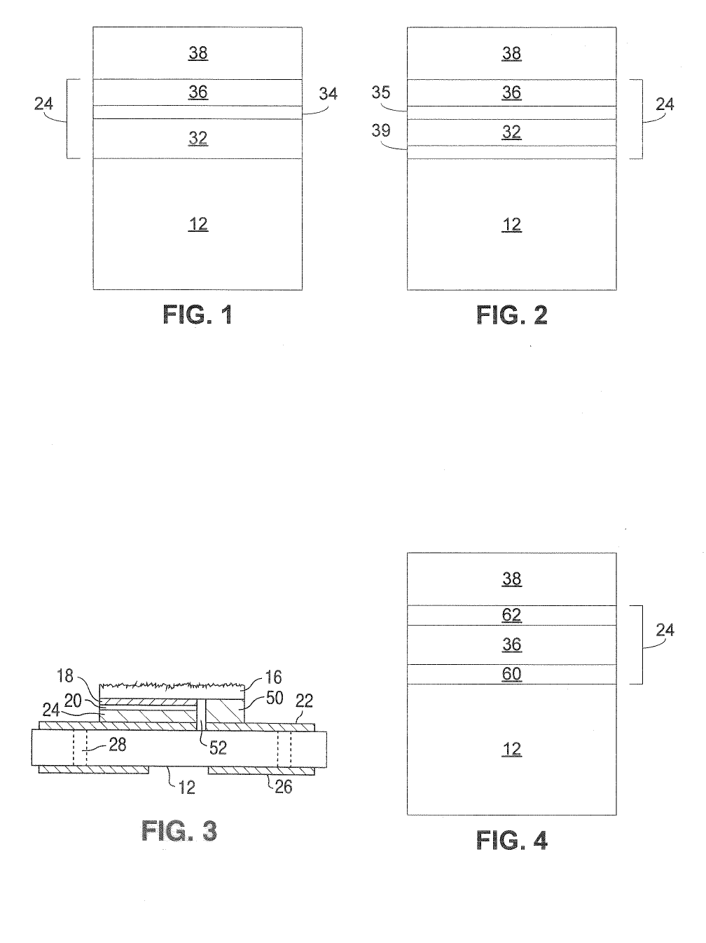

FIG. 1 illustrates a portion of a device according to embodiments of the invention. A p-contact 24 is formed on a p-type region of semiconductor structure 38. P-contact 24 includes multiple metal layers 32, 34, and 36. Layer 36, which is in direct contact with semiconductor structure 38, is a reflective metal such as silver. Layer 32 is also a reflective metal such as silver. Though in the examples herein, layers 32 and 36 are silver, layers 32 and 36 may be any suitably reflective contact metal.

A high electronegativity metal or semi-metal layer 34 is disposed between reflective metals 32 and 36. Examples of metals with suitably high electronegativity for layer 34 include nickel, molybdenum, ruthenium, rhodium, palladium, and platinum. Examples of semi-metals with suitably high electronegativity for layer 34 include selenium, tellurium, arsenic, and antimony. High electronegativity layer 34 generally has a higher electronegativity than reflective metals 32 and 36.

High electronegativity layer 34 may be very thin; for example, between four and twelve angstroms thick. Layer 34 may be a single, continuous thin sheet with the same pattern as reflective layers 32 and 36, though it need not be. Layer 34 is located far enough from the reflective metal 36/semiconductor 38 interface that is does not absorb a significant amount of light incident on the interface. Layer 34 is located far enough from the reflective metal 32/host 12 interface that it does not oxidize. In some embodiments, the interface between layers 34 and 36 is located between 500 and 1500 Å from the interface between layer 36 and semiconductor structure 38. In some embodiments, the interface between layers 34 and 32 is located between 200 and 800 Å from the interface between layer 32 and host 12. In some embodiments, layer 34 is located close enough to the metal-semiconductor interface that reflective layer 36 is not sufficiently thick to reflect all the light incident on the interface, and some light impinges on layer 34. In these embodiments, layers 36 and 32 are preferably the same highly reflective material such that reflective layer 32 reflects any light that penetrates layer 34.

P-contact 24 may be formed, for example, by evaporating, sputtering, electroplating, or any other suitable technique. During evaporation, first reflective layer 36 is evaporated on semiconductor structure 38, followed by high electronegativity layer 34, followed by second reflective layer 32. In some embodiments, after layers 32, 34, and 36 are deposited, p-contact 24 is annealed. Small amounts of the high electronegativity material of layer 34 may diffuse to close to the metal-semiconductor interface between reflective layer 36 and semiconductor structure 38 during the anneal, which may reduce the forward voltage of the device.

FIG. 2 illustrates a portion of a device including multiple layers 35 and 39. The first layer 35 is disposed between reflective metal layers 32 and 36. The second layer 39 is disposed between reflective metal layer 32 and host 12. First and second layers 35 and 39 may be the same material or different materials. In some embodiments, the properties of first layer 35 are selected to improve the forward voltage of the device, and the properties of second layer 39 are selected to reduce electro migration of the reflective metal in layer 32. For example, in some embodiments, the material of layer 35 is selected for high electronegativity. In some embodiments, the material of layer 39 is selected for its ability to gather and stabilize O₂, reducing the amount of oxygen that can contribute to the mobility of the reflective metal of layer 32, often Ag. Metals such as Al, Ni, Ti, Zn, which may have a higher propensity than silver to form a stable oxide, are preferred materials for layer 39. An oxygen stabilizing layer 39 must be thick enough to gather all the oxygen that diffuses into the p-metal layer. If layer 39 is not thick enough, it can become saturated, permitting oxygen to penetrate through layer to reflective layer 32. However, the oxygen-gathering material of layer 39 may form an alloy with reflective layer 32 which is less reflective than the layer 32 alone. Thus, layer 39 is thin enough to avoid causing an unacceptable reduction in overall reflectivity of p-contact 24. For example, layer 39 may be between 1 nm and greater than 100 nm thick, depending on processing details. Since O₂ usually comes in externally during processing, an oxygen gathering material in layer 39 can block O₂ from interacting with silver. Since a good oxygen gatherer is not necessary a high electronegative material, a contact including multiple layers with separate functionalities may yield better results than a contact with a single high electronegativity layer.

In some embodiments, layer 39 is capped by an additional metal layer (not shown in FIG. 2) disposed between layer 39 and host 12. The cap layer may protect layer 39 from excessive oxidation while layer 39 is exposed to air.

FIG. 4 illustrates a portion of a device including one or more alloy layers. Alloy layer 62, which is formed in direct contact with semiconductor structure 38, is an alloy of a reflective metal and a metal with high electronegativity, such as the high electronegativity metals listed above in reference to FIG. 1. In some embodiments, alloy layer 62 is between 0.3 and 3% high electronegativity metal, with a thickness between 500 and 1000 Å. For example, alloy layer 62 may be a silver/nickel alloy.

A reflective metal layer 36, silver in some embodiments, is formed over alloy layer 62.

In some embodiments, an optional second alloy layer 60 is formed over reflective layer 36. Alloy layer 60 is an alloy of a reflective metal and one or more other materials. The one or more other materials may include, for example, a high electronegativity material as listed above in reference to FIG. 1, or an oxygen-gathering material as listed above in reference to FIG. 2. In some embodiments, alloy layer 60 is a reflective metal/oxygen-gathering metal alloy that is between 0.5 and 40% oxygen-gathering metal, with a thickness between 500 and 1500 Å. Second alloy layer 60 may be capped by an additional metal layer disposed between alloy layer 60 and host 12.

Alloys 60 and 62 may be formed, for example, by evaporating, sputtering, electroplating, or any other suitable technique.

The embodiments described above may offer several advantages. The presence of a high electronegativity material increases the overall electronegativity of the contact, which leads to a better p-contact. Electro migration, which may be caused by oxidation of the silver, may be reduced because increasing the electronegativity of the contact may suppress silver oxidation. An oxygen-gathering material which caps the reflective metal, as illustrated in FIGS. 2 and 4, may also suppress oxidation and thereby reduce electro migration of the reflective metal. In addition, since an ohmic metal layer between the reflective metal and the semiconductor is not required, a device including the contacts described above may have better light output than a device including an absorbing ohmic metal layer.

The embodiments described herein may be used with any suitable device design that requires reflective contacts.

FIG. 3 illustrates one example of a suitable device design, a III-nitride flip-chip, thin-film LED described in more detail in U.S. Pat. No. 7,256,483, which is incorporated herein by reference. A semiconductor structure (structure 38 in FIGS. 1 and 2) including n-type layers 16, one or more light emitting layers in an active region 18, and p-type layers 20 is grown over any suitable substrate, such as, for example, sapphire or SiC. The p-layer surface is highly doped to form an ohmic contact with p-contact 24, which may be any of the p-contacts described above. Contact 24 is reflective to light emitted by the active layer. Portions of the p-layer 20 and active layer 18 are etched away during the LED forming process, and metal 50 (contact metallization layer plus bonding metal) contacts the n-layer 16 on the same side of the device as p-contact 24.

The n-contact 50 and p-contact 24 are bonded to the pads 22 on a package substrate 12. An under fill material 52 may be deposited in the voids beneath the LED to reduce thermal gradients across the LED, to add mechanical strength to the attachment, and to prevent contaminants from contacting the LED material. The bond technology may be solder, thermo compression, interdiffusion, or a gold stud bump array bonded by an ultrasonic weld. The combination of the die metallization and bond material is shown as metals 24 and 50 and may include a diffusion barrier or other layers to protect the optical properties of the metallization layer adjacent the semiconductor material. The package substrate 12 may be formed of the electrically insulating material AlN, with gold contact pads 22 connected to solderable electrodes 26 using vias 28 and/or metal traces. Alternatively, the package substrate 12 may be formed of a conducting material if passivated to prevent shorting, such as anodized AlSiC. The package substrate 12 may be thermally conductive to act as a heat sink or to conduct heat to a larger heat sink.

The growth substrate may be removed using an excimer laser beam. The laser beam melts the GaN material at its interface with the growth substrate, allowing the growth substrate to then be lifted off. Alternatively, the growth substrate may be removed by etching such as RIE etching, by liftoff techniques such as etching away a layer between the growth substrate and the LED layers, or by lapping.

The exposed, relatively thick n-type region 16 (often a GaN layer) is optionally thinned by etching using a dry etch such as RIE. In one example, the thickness of the GaN layer 16 being etched is 7 μm, and the etching reduces the thickness of the GaN layer 16 to approximately 1 μm. If the initial thickness of all the epitaxial LED layers is 9 μm, in this case the etching causes the total thickness of the LED layers to be 3 μm. The total thickness of the semiconductor structure in a finished device may be 10 μm or less in some embodiments, 5 μm or less in some embodiments, 2 μm or less in some embodiments, and 1 μm or less in some embodiments. The thinning process removes damage caused by the laser lift off process, and reduces the thickness of the optically absorbing layers that are no longer needed, such as a low temperature GaN nucleation layer and adjacent layers. All or a portion of the n-type cladding layer adjacent to the active region is left intact.

The top surface of the LED (n-layer 16) is textured for increased light extraction. In one embodiment, layer 16 is photo-electrochemically etched using a KOH solution 46. This forms a “white” roughness in the GaN surface (having n-type Si doping). This etching process can also be used to further thin the n-layer 16 and stop at a predetermined thickness using an etch stop layer grown during the LED formation process, leaving a smooth surface. This latter approach is useful for resonant device designs. For such devices, a mirror stack (e.g., a Bragg reflector) may now be deposited on the top surface of the LED. Additional light extraction techniques could include micron or nanometer scale patterned etching (dimple or photonic crystal).

Though in the example above, the growth substrate is removed from the device, it need not be.

Having described the invention in detail, those skilled in the art will appreciate that, given the present disclosure, modifications may be made to the invention without departing from the spirit of the inventive concept described herein. For example, though the contacts in the examples described above are formed on p-type semiconductor materials, in some embodiments they are formed on n-type semiconductor materials. In addition, the invention is not limited to the contact materials or semiconductor materials described in the examples above. Therefore, it is not intended that the scope of the invention be limited to the specific embodiments illustrated and described.

What is being claimed is:

1. A light emitting device comprising:
a semiconductor structure comprising a light emitting layer disposed between an n-type region and a p-type region;
a contact formed on the semiconductor structure, the contact comprising:
a first material in direct contact with the semiconductor structure, wherein the first material comprises a metal that is reflective of light emitted by the light emitting layer; and
a second material disposed within the first material, wherein the second material is a different material than the first material.

2. The light emitting device of claim 1 wherein the second material has a higher electronegativity than the first material.

3. The light emitting device of claim 1 wherein the first material and second material are combined in a single alloy layer.

4. The light emitting device of claim 1 wherein the second material is confined to a layer disposed within the first material, wherein the layer of second material is substantially free of the reflective metal of the first material.

5. The light emitting device of claim 4 wherein:
the light emitting layer is a III-nitride layer;
the first material comprises silver; and
the second material comprises nickel.

6. The light emitting device of claim 4 wherein the second material is one of nickel, molybdenum, ruthenium, rhodium, palladium, platinum, selenium, tellurium, arsenic, and antimony.

7. The light emitting device of claim 4 wherein:
the first material is divided into a first portion disposed between the layer of second material and the semiconductor structure, and a second portion disposed on a side of the layer of second material opposite the first portion; and
the first portion has a thickness between 500 and 1500 Å.

8. The light emitting device of claim 4 wherein:
the first material is divided into a first portion disposed between the layer of second material and the semiconductor structure, and a second portion disposed on a side of the layer of second material opposite the first portion; and
the second portion has a thickness between 200 and 800 Å.

9. The light emitting device of claim 4 wherein the layer of second material has a thickness between 4 and 12 Å.

10. The light emitting device of claim 1 wherein:
the first material is divided into a first portion proximate the semiconductor structure and a second portion;
the contact further comprises a third material; and
the second portion of the first material is disposed between the second material and the third material, the second portion of the first material being substantially free of the second and third materials.

11. The light emitting device of claim 8 wherein the third material is the same as the second material.

12. The light emitting device of claim 8 wherein the third material is different from the second material.

13. The light emitting device of claim 8 wherein the second material is combined with the first portion of the first material in an alloy.

14. The light emitting device of claim 8 wherein:
the first material is further divided into a third portion; and
the third material is combined with a third portion in an alloy.

15. The light emitting device of claim 8 wherein the third material comprises one of nickel, molybdenum, ruthenium, rhodium, palladium, platinum, selenium, tellurium, arsenic, and antimony.

16. The light emitting device of claim 8 wherein:
the second material has a higher electronegativity than the first material; and
the third material oxidizes more readily than silver.

17. The light emitting device of claim 8 wherein the third material is one of Al, Ni, Ti, and Zn.
